(19) United States
(12) Patent Application Publication
(10) Pub. No.: US 2013/0182916 A1
(43) Pub. Date: Jul. 18, 2013

(54) CUSTOM ELECTRONIC SYSTEM OF IRIS PATTERN MATCHING IN A MOBILE DEVICE

(71) Applicants: STEVE FIELDING, (US); LIQUN LARRY WANG, (US)

(72) Inventors: STEVE FIELDING, (US); LIQUN LARRY WANG, (US)

(21) Appl. No.: 13/351,583

(22) Filed: Jan. 17, 2012

(51) Int. Cl. G06K 9/00; G06F 13/14; G06F 11/08; G06F 12/02; H03M 13/09

(52) U.S. Cl. 382/117; 711/103; 714/758; 710/305; 714/E11.03; 711/E12.008

(57) ABSTRACT

A method, apparatus, and system for a custom electronic hardware for iris pattern matching in a mobile device. In one embodiment, a method of a custom hardware solution that includes a change in the CPU clock frequency dependency by using programmable logic and a highly parallel array of high capacity flash memory is shown.

### FIELD OF TECHNOLOGY

This disclosure relates generally to the field of mobile technology and in one embodiment to a method, apparatus, and system for a custom electronic hardware for iris pattern matching in a mobile device.

### DISCLOSURE

An iris recognition algorithm identifies the approximately concentric circular outer boundaries of the iris and the pupil in a photo of an eye from which the iris is rendered in pixel sets. These pixel set or sets are transformed into a bit pattern that may be a means of preserving the data that is essential for a statistically meaningful comparison between two iris images.

By discarding amplitude information in an algorithm, it is ensured that a biometric template may remain largely unaffected by changes in illumination and virtually negligibly by iris color, which contributes significantly to the long-term stability of the template. Authentication via identification which may be provided by one-to-many template matching or verification which may be provided by one-to-one template matching shows how a template created by imaging the iris is compared to a stored value template in a database.

Each Iris template is 2048 bits; IR matching speed is the primary factor which is considered especially for a large population, such as a million iris codes enrolled in the UAE central database.

Iris recognition algorithm is designed to match a new template with one previous enrolled based on the predetermined factional Hamming distance. This continuous exhaustive comparison is conducted by sequentially central processing unit (CPU)-based system. Search speed scales linearly with CPU frequency, hence an Iris database searches may require faster CPUs. These databases are generally stored on hard drives or solid state drives.

CPUs that have a higher frequency use a lot of power which creates heat in the device. To replicate the same search in a mobile device requires a large battery. The requirement for heat sinking and a large battery adds weight and increases the size of a mobile product. CPUs can only access standard storage devices which may not offer the ideal combination of storage capacity, speed and mechanical robustness.

In the desk top type PC, the faster CPU requires a cooling fan, heat sink and heat pipe for heat dissipation. In portable, hand-held mobile identification application, some of approaches are not permitted in a rugged environment, such as a cooling fan. The demand for the higher performance may mainly be restricted by the heat dissipation and battery life.

### BRIEF DESCRIPTION OF FIGURES

Example embodiments are illustrated by way of example and not limitation in the figures of the accompanying drawings, in which like references indicate similar elements and in which:

FIG. 1 is a high level view of the invention being used in a mobile iris pattern matching application.

FIG. 2 is a block view which illustrates a hardware block diagram of a pattern matching module (PMM) 100, according to one embodiment.

FIG. 3 is a block view which illustrates a pattern matching module 100 incorporated in a complete system, according to one embodiment.

FIG. 4 is a block view which illustrates the pattern matching process flow. Data is read from a pattern database 201 stored in a NAND flash array, according to one embodiment.

FIG. 5 is a block view which illustrates the Host system 210 write access to the pattern matching module, according to one embodiment.

### DETAILED DESCRIPTION

A method, apparatus, and system for a custom electronic hardware for iris pattern matching in a mobile device. Although the present embodiments have been described with reference to specific example embodiments, it will be evident that various modifications and changes may be made to these embodiments without departing from the broader spirit and scope of the various embodiments. In another embodiment the iris pattern matching algorithm may be replaced by another pattern matching algorithm, such as a finger print matching algorithm, or any other pattern matching algorithm.

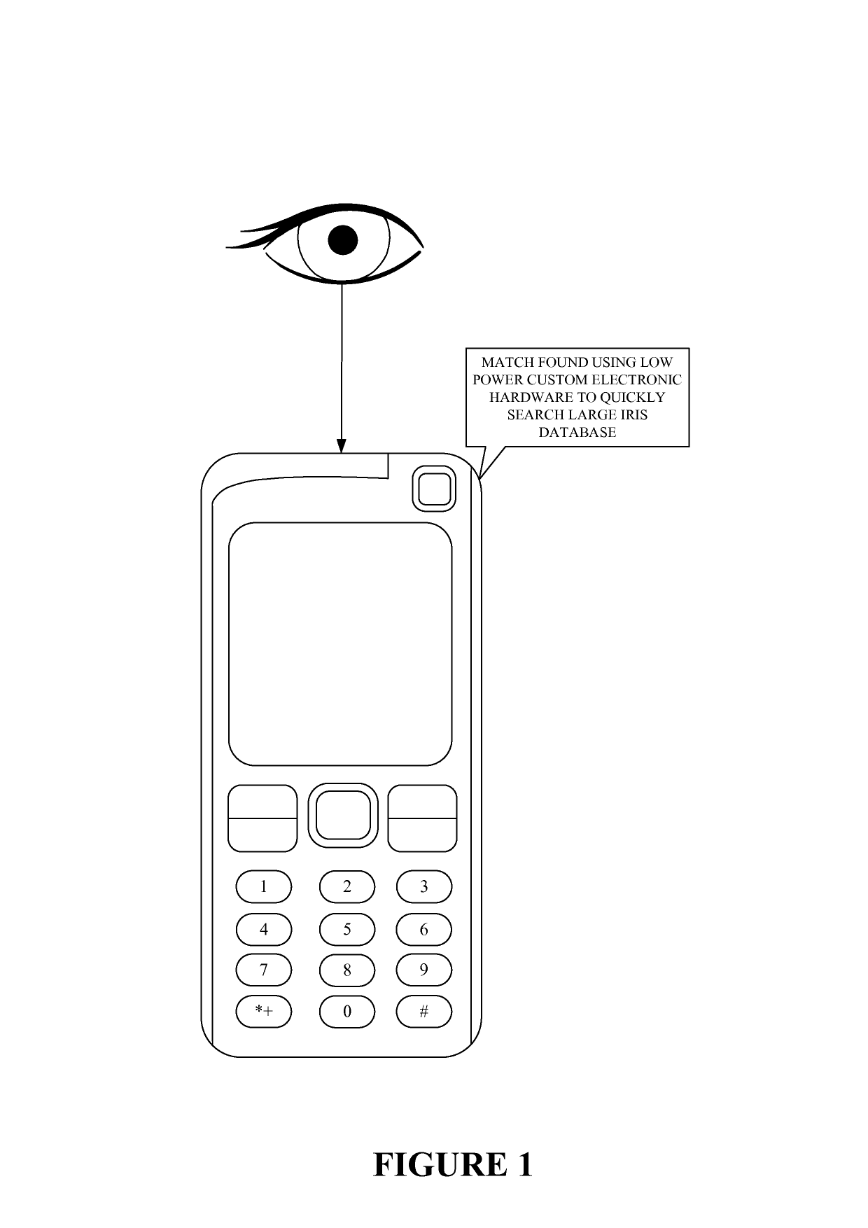

What is disclosed here is, a method, apparatus, and system for a custom electronic hardware for iris pattern matching in a mobile device. FIG. 1 shows an example application 150 where a persons iris is scanned using a mobile device. The mobile device, incorporating a Pattern Matching Module (PMM), compares the scanned iris against an iris pattern database and determines if there is a match.

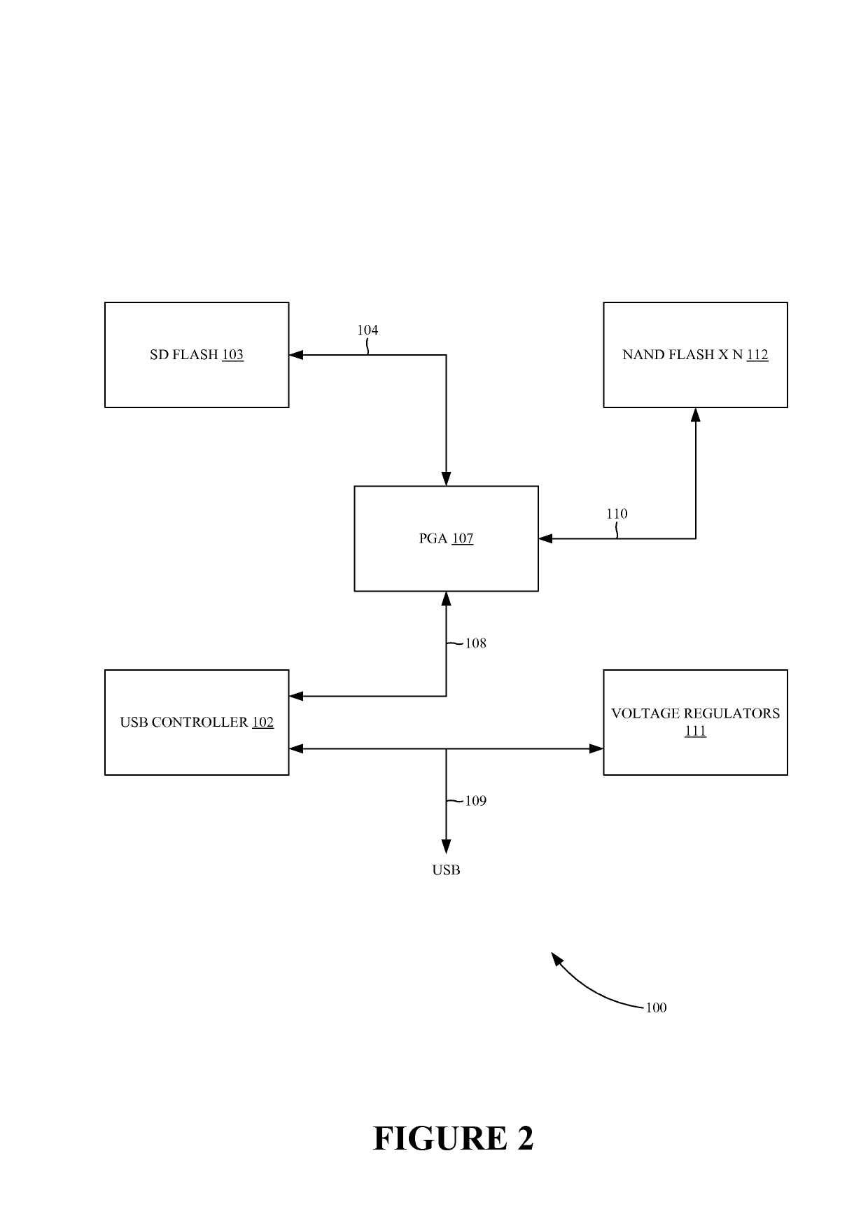

(Refer to FIG. 2), which shows a hardware block diagram of a Pattern Matching Module (PMM) 100. This is the central component of the invention, and performs the pattern matching between a pattern database and a target pattern. The pattern database may be stored in a NAND Flash memory array 112. The NAND Flash array comprises of two or more NAND flash memory devices arranged so that their data buses are coupled in parallel, via a parallel data bus 110, to a Programmable Gate Array (PGA) 107. The pattern database is loaded into the NAND flash memory via the USB interface 109, USB Controller 102, parallel data bus 108, and PGA 107. The target pattern may be stored in memory inside the PGA 107, and the target pattern memory is also loaded via the USB 109 interface. NAND flash memory suffers from bit errors, and these must be detected and corrected. The PGA 107 device provides bad block mapping, Error Correcting Code (ECC) generation, ECC error detection and ECC error correction. A SD Flash card 103 may be used to store the NAND flash bad block table. The SD flash card may also be used to store the configuration files required to initialize the PGA 107. The PGA 107 may access the SD flash 103 via a serial interface 104. Power for the board may be supplied by the USB interface and may be regulated on board by the voltage regulators 111.

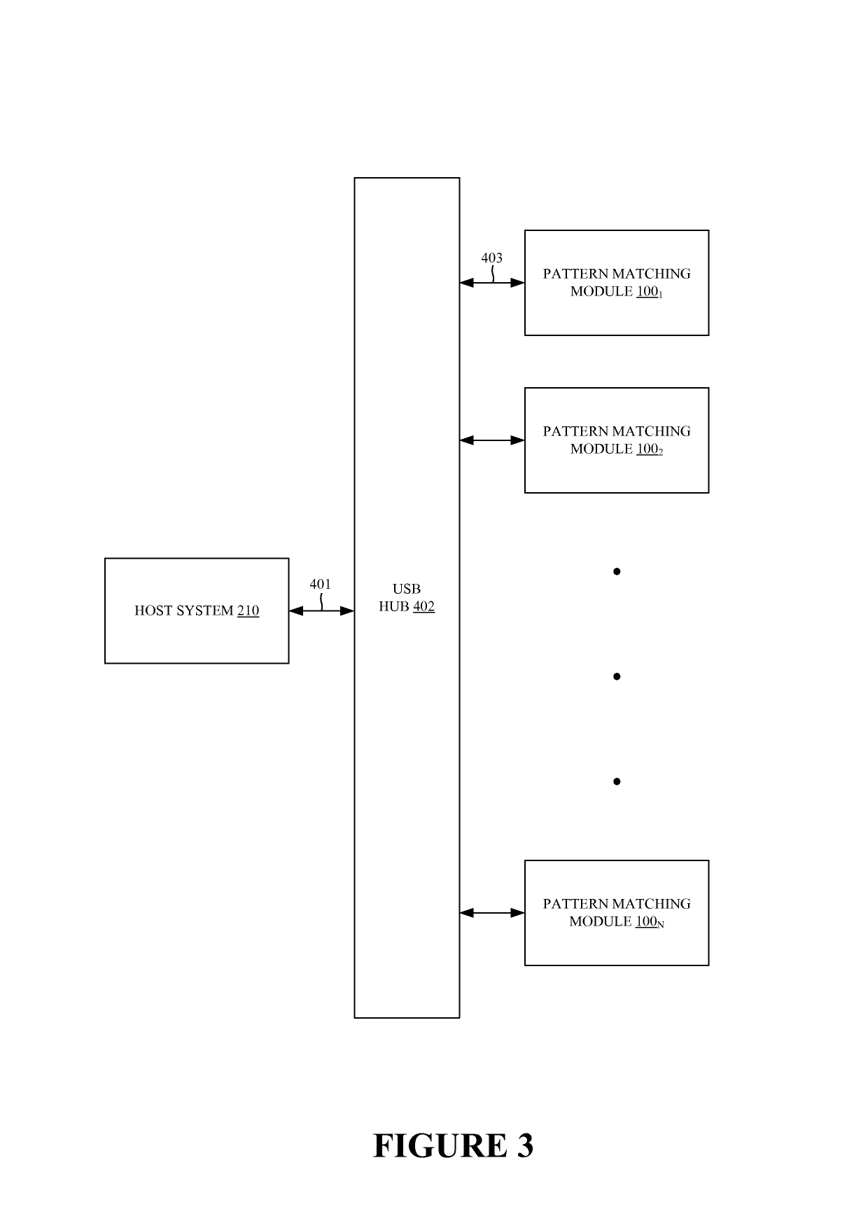

FIG. 3 illustrates a pattern matching module 100 incorporated in a complete system. One or more pattern matching modules 100 may be combined in parallel via one or more USB interfaces 403. If the host system 210 has enough USB interfaces 401 to service all the pattern matching modules, then the host system may be coupled directly. Otherwise a USB hub 402 may be used to couple the pattern matching module to the host system 210. When multiple PMMs are used in a system the pattern database may be split across PMMs. A search is then performed by loading the same target pattern onto every PMM and requesting each PMM to search its pattern database.

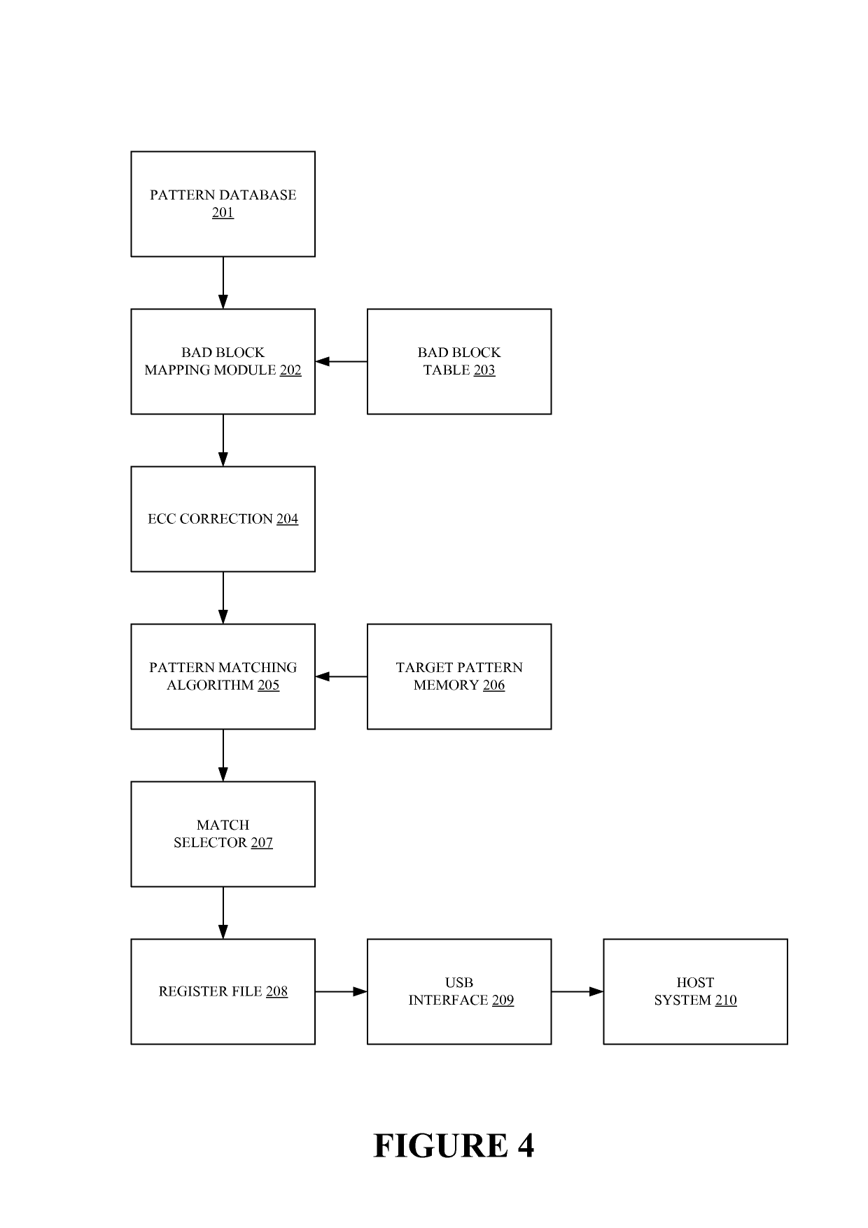

FIG. 4 illustrates the pattern matching process flow. Data is read from a pattern database 201 stored in a NAND flash array. To avoid reading data from bad blocks in the NAND flash memory, a bad block mapper 202 remaps known bad blocks as identified by the bad block table 203, which resides in SD Flash memory. Data from the pattern database undergoes ECC correction 204 before being presented to the pattern matching algorithm 205, where it is compared with a target pattern 206. A match selector 207 saves the index and score for the pattern in the database which best matches the target pattern. The final results of the search are copied to a register file 208 which may be accessed by the host system 210 via the USB interface 209.

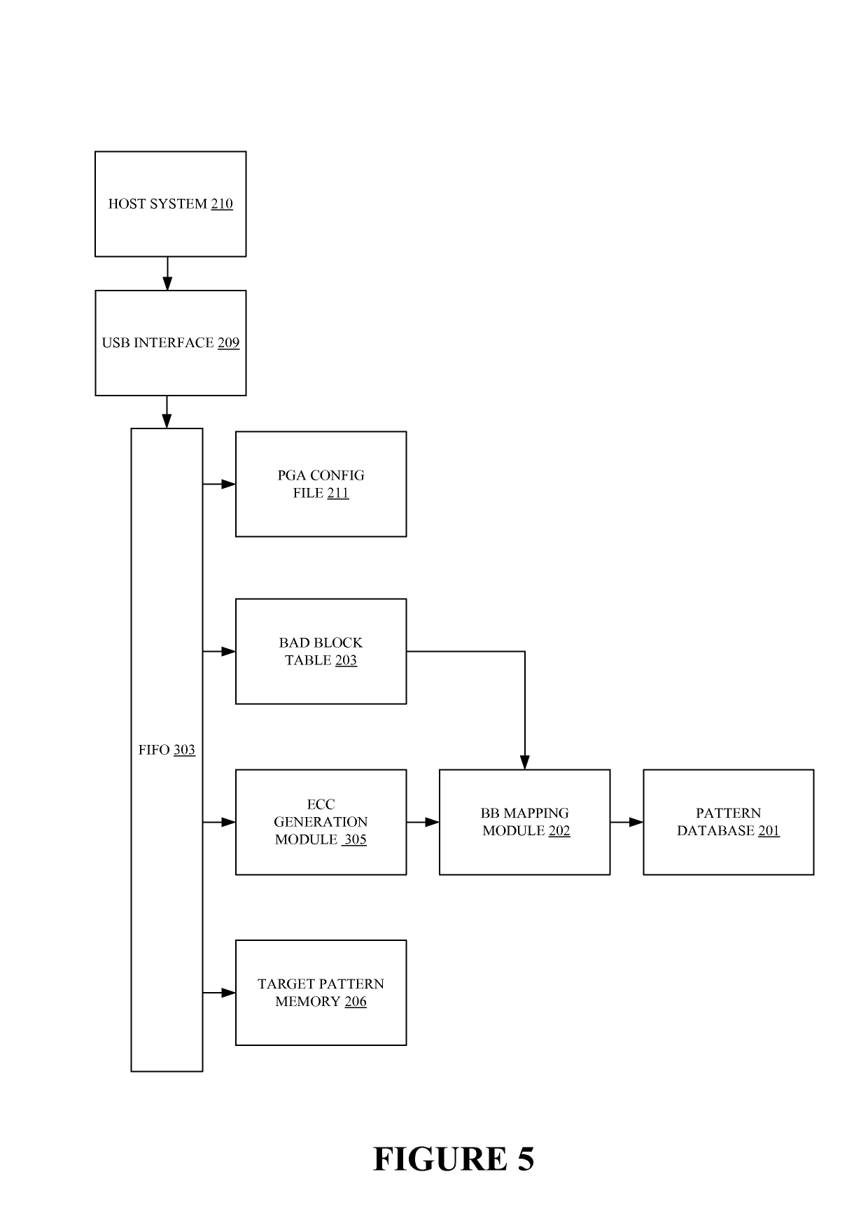

FIG. 5 shows the Host system write access to the pattern matching module. The host system 210 may have write access to the pattern database 201, PGA configuration file 211, NAND flash bad block table 203, and target pattern memory 206. All these memory locations are accessed by the host system 210 via the USB Interface 209 and a FIFO memory 303. Data written to the pattern database 201 must first have a ECC added to the data by the ECC generation module 305, and then the data address must be remapped to avoid NAND flash bad blocks. Remapping is performed by the bad block mapping module 202, which remaps the data according to information in the bad block table 203.

1. An apparatus comprising:
a Universal Serial Bus (USB) interface to communicate with a host processor;
a USB controller to bridge between the USB interface and a Programmable Gate Array (PGA) wherein the PGA to performs a pattern matching operation, to communicate with the USB controller, to access a NAND flash memory, and to access Secure Digital (SD) flash memory; an array of the NAND flash memory to store a pattern database, wherein the array of the NAND flash memory is arranged so that data buses are coupled in parallel to the PGA; and a SD flash memory card to store the PGA configuration files and a NAND flash bad block information.

2. The apparatus of claim 1, wherein a number and a capacity of the NAND flash memory ICs is variable according to storage requirements and pattern matching speed required in an application.

3. The apparatus of claim 1, wherein a SPI flash or NOR flash memory is used in place of the NAND flash memory.

4. A method comprising:
loading a pattern database into a parallel array of NAND flash memory;
managing NAND flash storage corruption and bad blocks;
loading a target pattern into a PGA;
comparing a NAND flash database with the target pattern;
providing search match results to a host system; and
configuring the PGA from files stored on the SD card.

5. The method of claim 4, wherein the NAND flash contents are protected against corruption by an addition of Error Correcting Codes (ECC) such as Hamming, Reed-Solomon and BCH algorithm.

6. The method of claim 4, wherein a comparison between a target pattern and a database pattern can use different distance measures, such as bit exact, Hamming distance, Euclidian distance and correlation distance.

7. The method of claim 4, further comprising storage of associated data on the SD card, that is information associated with a pattern database such as persons name, etc in the case of a biometrics database.

8. The method of claim 4, wherein multiple PGA configuration files can be stored on a SD card and loaded into a PGA.

9. A mobile device comprising:
a processor to perform a pattern matching operation;
a controller to communicate with the processor;
an array of a NAND flash memory arranged so that data buses of each of the NAND flash memory in the array are coupled in parallel with the processor; and
an SD flash memory card to store a configuration file of the processor and a bad block information of the array of the NAND flash memory.

10. The mobile device of claim 9 wherein the pattern matching operation is at least one of an iris scan operation, a fingerprint scan operation, and a tactile detection operation.

11. The mobile device of claim 9 wherein the controller is at least one of a universal serial bus controller, a Bluetooth controller, a Zigbee controller, a WiFi controller, WiMax controller, PoE controller, Wibree controller, RS-232 controller, RS-422 controller, RS-485 controller, and an Ethernet controller.

12. The mobile device of claim 9 wherein the processor is a Programmable Gate Array (PGA).
